(19) United States
(12) Patent Application Publication
(10) Pub. No.: US 2006/0249800 A1
(43) Pub. Date: Nov. 9, 2006

(54) Semiconductor device and method of manufacturing the same

(75) Inventor: Masayuki Tanaka, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Kabushiki Kaisha Toshiba

(21) Appl. No.: 11/482,911

(22) Filed: Jul. 10, 2006

Related U.S. Application Data
(63) Continuation of application No. 10/633,615, filed on Aug. 5, 2003.

(30) Foreign Application Priority Data
Oct. 15, 2002 (JP) 2002-299918

(51) Int. Cl. H01L 29/78; H01L 21/4763

(52) U.S. Cl. 257/413; 438/592; 257/757; 438/783

(57) ABSTRACT

A semiconductor device comprises a semiconductor substrate, source/drain regions provided in the semiconductor substrate, a gate insulating film provided on a channel region between the source/drain regions, a gate electrode provided on the gate insulating film, a conductive layer of a metal silicide provided on the gate electrode and the source/drain regions, an insulating film containing carbon provided on the semiconductor substrate so as to be in contact with at least the conductive layer, and an interlayer insulating film provided on the semiconductor substrate so as to cover the insulating film containing carbon.

### CROSS-REFERENCE TO RELATED APPLICATIONS

This application is based upon and claims the benefit of priority from the prior Japanese Patent Application No. 2002-299918, filed Oct. 15, 2002, the entire contents of which are incorporated herein by reference.

### BACKGROUND OF THE INVENTION

1. Field of the Invention

The present invention relates to a semiconductor device using a silicon nitride film, and particularly, to a semiconductor device, having a silicon nitride film not to degrade a characteristic of a metal silicide used as a conductive layer, and realizing a high performance thereof, and a method of manufacturing the same.

2. Description of the Related Art

In order to reduce electrode resistance in a semiconductor device of the next generation, a metal silicide such as nickel silicide has been employed. FIG. 8 shows a prior semiconductor device in which a metal silicide is used in a conductive layer such as an electrode.

That is, a silicon semiconductor substrate 101 is, for example, of a P-type and the figure is of a sectional view of a MOSFET formed on the substrate. Such a MOSFET is used in, for example, a CMOS structure in which an NMOS and a PMOS are fabricated in the same chip.

A MOSFET is formed in an element region defined by an isolation region 113 such as STI (Shallow Trench Isolation) on the semiconductor substrate 101. In a surface region of the semiconductor substrate 101, there are provided source/drain regions including a shallow diffusion region (an extension region) 102 and a deep diffusion region 103. A gate insulating film 104 such as a silicon oxide film is provided on a channel region between the source/drain regions. A gate electrode 107 made of polysilicon is formed on the gate insulating film 104, an insulating film 105 such as a silicon oxide film is formed on a surface of the gate electrode 107 and a sidewall insulating film 106 of a silicon nitride film or the like is formed on a side wall of the gate electrode 107 with the insulating film 105 interposed therebetween.

A conductive layer 109 of a metal silicide such as nickel silicide is formed on the top surface of the gate electrode 107. The conductive layer 109 is provided in order to reduce the resistance of the gate electrode 107. Similarly, the conductive layer 109 is also formed on the source/drain regions in order to reduce the resistance of the source/drain regions.

A silicon nitride film 110 is formed on the semiconductor substrate 101 so as to cover the gate structure and the source/drain regions. An interlayer insulating film 111 such as a silicon oxide film made by CVD or the like is formed on the semiconductor substrate 101 so as to cover the silicon nitride film 110. The interlayer insulating film 111 is planarized at its surface and in the interlayer insulating film 111, there is formed a contact hole to be filled with a contact 112 for connecting a wiring layer (not shown) formed on the interlayer insulating film 111 electrically to the source/drain regions. The contact hole is provided to expose a surface of the conductive layer 109 on a source/drain region, and the contact 112 of tungsten or the like buried in the contact hole connects electrically the wiring layer to the conductive layer 109. The contact hole is formed with anisotropic etching such as RIE, and on this occasion, the silicon nitride 110 is used as an etching stopper.

Since the metal silicide, especially, nickel silicide, is lower in heat resistance compared with a conventional electrode material, it is necessary that a heat treatment after formation of the nickel silicide is lowered to 500° C. or less. In addition to nickel, there are metals for forming silicides such as Co, Mo, W, Ti, Ta, Hf, Pt and the like, but a silicide of any of the metals is low in heat resistance and, for example, a heat resistance of Co silicide is 550° C., that of Mo silicide is 650° C. and that of W silicide is about 500° C. or more.

For forming a semiconductor device, silicon nitride (SiN) is used as an etching stopper in a process described above. However, the nitride must be formed at a temperature of 700° C. or less, and preferably 500° C. or less, considering the heat resistance of the metal silicide such as nickel silicide.

A method for forming a silicon nitride film (SiN) on a semiconductor substrate from a silicon source including a silane is well known as described in Jpn. Pat. Appln. KOKAI Publication No. 11-172439. Furthermore, a film formation for adding carbon to a silicon nitride film (SiN) is described in Jpn. Pat. Appln. KOKAI Publication No. 2001-168092.

Conventionally, as techniques to form a low temperature silicon nitride film (SiN), there is given a film formation method using hexachlorodisilane (Si₂Cl₆:HCD) as a silicon source. However, if a silicon nitride film is formed on a nickel silicide film using a silicon source including chlorine, the nickel silicide on an arsenic- or phosphorus-added electrode will be etched by hydrogen chloride generated during film formation.

### BRIEF SUMMARY OF THE INVENTION

According to a first aspect of the present invention, there is provided a semiconductor device comprising: a semiconductor substrate; source/drain regions provided in the semiconductor substrate; a gate insulating film provided on a channel region between the source/drain regions; a gate electrode provided on the gate insulating film; a conductive layer of a metal silicide provided on the gate electrode and the source/drain regions; an insulating film containing carbon provided on the semiconductor substrate so as to be in contact with at least the conductive layer; and an interlayer insulating film provided on the semiconductor substrate so as to cover the insulating film containing carbon.

According to a second aspect of the present invention, there is provided a method of manufacturing a semiconductor device, comprising: forming source/drain regions in a silicon semiconductor substrate; forming a gate insulating film on a channel region between the source/drain regions; forming a gate electrode of polysilicon on the gate insulating film; forming a conductive layer of a metal on the semiconductor substrate so as to cover the gate electrode and the source/drain regions; heat-treating the conductive layer to form a conductive metal silicide, obtained by a reaction of the silicon and the polysilicon with the metal, on the source/drain regions and the gate electrode; removing the metal unreacted with the silicon and the polysilicon; forming an insulating film containing carbon on the semiconductor substrate so as to cover the conductive layer of a metal silicide; and forming an interlayer insulating film over the semiconductor substrate so as to cover the insulating film containing carbon.

### BRIEF DESCRIPTION OF THE DRAWINGS

FIG. 1 is a sectional view showing a semiconductor device according to a first embodiment.

FIG. 2 is a sectional view showing a part of a process of manufacturing the semiconductor device in FIG. 1.

FIG. 3 is a sectional view showing a part of the process of manufacturing the semiconductor device in FIG. 1.

FIG. 4 is a sectional view showing a part of the process of manufacturing the semiconductor device in FIG. 1.

FIG. 5 is a sectional view showing a part of the process of manufacturing the semiconductor device in FIG. 1.

FIG. 6 is a characteristic graph showing results of a SIMS analysis on impurities in a silicon nitride film formed with a method according to the first embodiment.

FIG. 7 is a sectional view showing a semiconductor device according to a second embodiment.

FIG. 8 is a sectional view showing a conventional semiconductor device.

### DETAILED DESCRIPTION OF THE EMBODIMENTS

Description will be given of embodiments below with reference to the accompanying drawings.

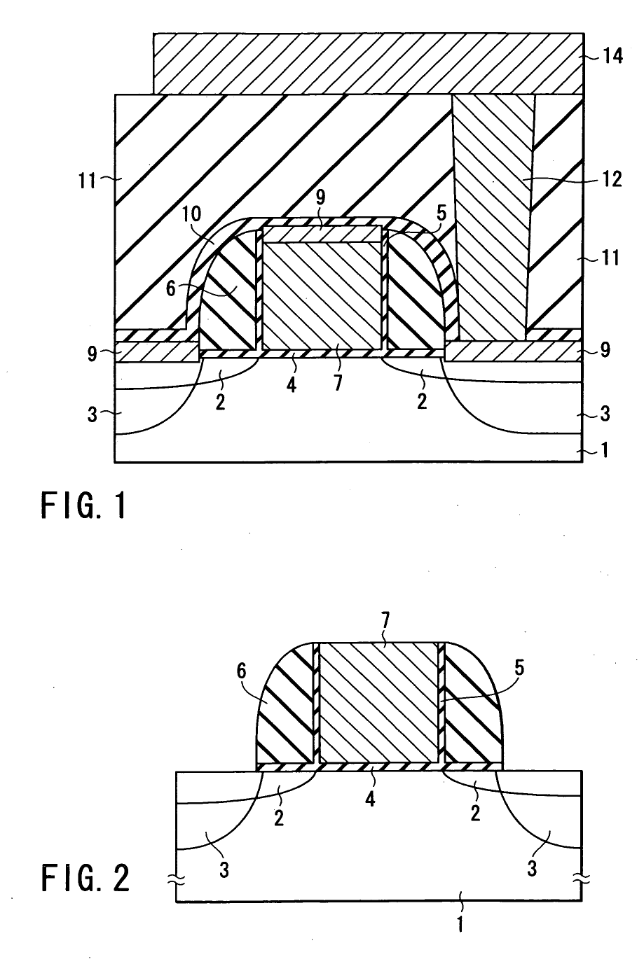

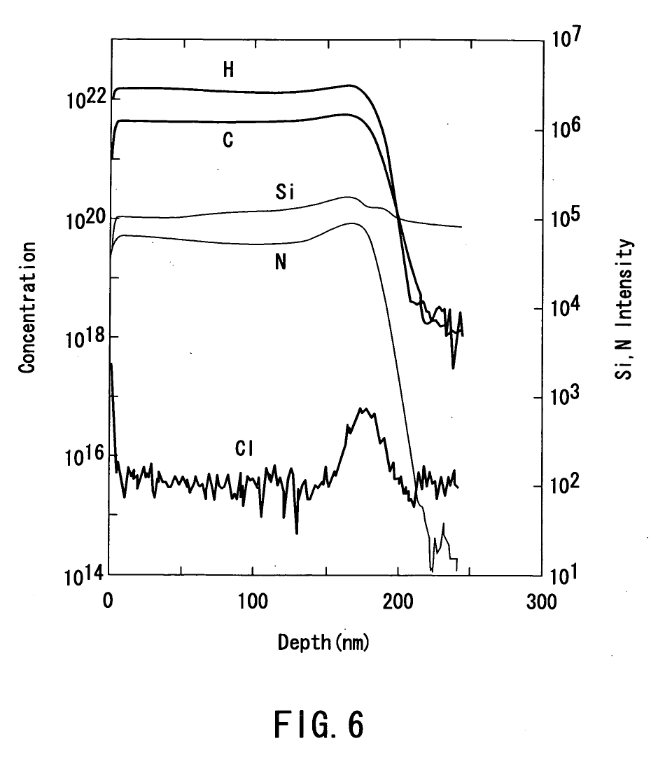

FIGS. 1 to 6 show a first embodiment and FIG. 1 is a sectional view of a semiconductor device and FIGS. 2 to 5 are sectional views showing a process of manufacturing the semiconductor device. FIG. 6 is a characteristic graph showing results of a SIMS analysis on impurities in a silicon nitride film (SiN) formed with a method according to the first embodiment.

In FIG. 1, a silicon substrate 1 is, for example, of a P-type, in which an NMOSFET is provided. Such a MOSFET is employed in a CMOS structure in which an NMOS and a PMOS are both fabricated in the same chip. On the semiconductor substrate 1, there is fabricated a MOSFET in an element region defined by an isolation region (not shown) such as STI.

In a surface region of the semiconductor substrate 1, there are formed source/drain regions including shallow diffusion regions (extension regions) 2 and deep diffusion regions 3. A gate insulating film 4 such as a silicon oxide film is formed on a channel region between the source/drain regions.

A gate electrode 7 of polysilicon is formed on the gate insulating film 4 and an insulating film 5 such as silicon oxide is formed on a surface of the gate electrode 7 and a sidewall insulating film 6 of a silicon nitride film is formed on a sidewall of the gate electrode 7. The sidewall insulating film 6 surrounds the gate insulating film 4 and the insulating film 5.

Furthermore, a conductive layer 9 of a metal silicide such as nickel silicide is formed on the top surface of the gate electrode 7. The conductive layer 9 is provided in order to decrease the resistance of the gate electrode 7. Similarly, the conductive layer 9 is also formed on the source/drain regions to decrease the resistance thereof.

A silicon nitride film 10 containing carbon is formed above the semiconductor substrate 1 so as to cover the gate structure and the source/drain regions. An interlayer insulating film 11 such as a silicon oxide film is formed over the semiconductor substrate 1 so as to cover the silicon nitride film 10. The interlayer insulating film 11 is planarized at its surface, and in the interlayer insulating film 11, there is formed a contact hole to be filled with a contact 12 for electrically connecting a wiring layer 14 of aluminum or copper to the source/drain regions. The contact is provided to expose a surface of the conductive layer 9 on the source/drain region, and the contact 12 of tungsten or the like buried in the contact hole connects electrically the wiring layer 14 to the conductive layer 9. The contact hole is formed with anisotropic etching such as RIE, and on this occasion, the silicon nitride 10 containing carbon is used as an etching stopper.

By using the silicon nitride film containing carbon employed in this embodiment, a dielectric constant will be reduced and reduction in speed of a transistor called as an RC delay will be suppressed.

Then, referring to FIGS. 1 to 5, a method of manufacturing the semiconductor device of this embodiment will be described. The source/drain regions including the shallow diffusion region 2 and the deep diffusion region 3 are at first formed in the semiconductor substrate 1, and the gate structure is formed on between the source/drain regions through the gate insulating film 4. As shown in FIG. 2, in this state, the gate electrode 7 and surfaces of the source/drain regions are exposed.

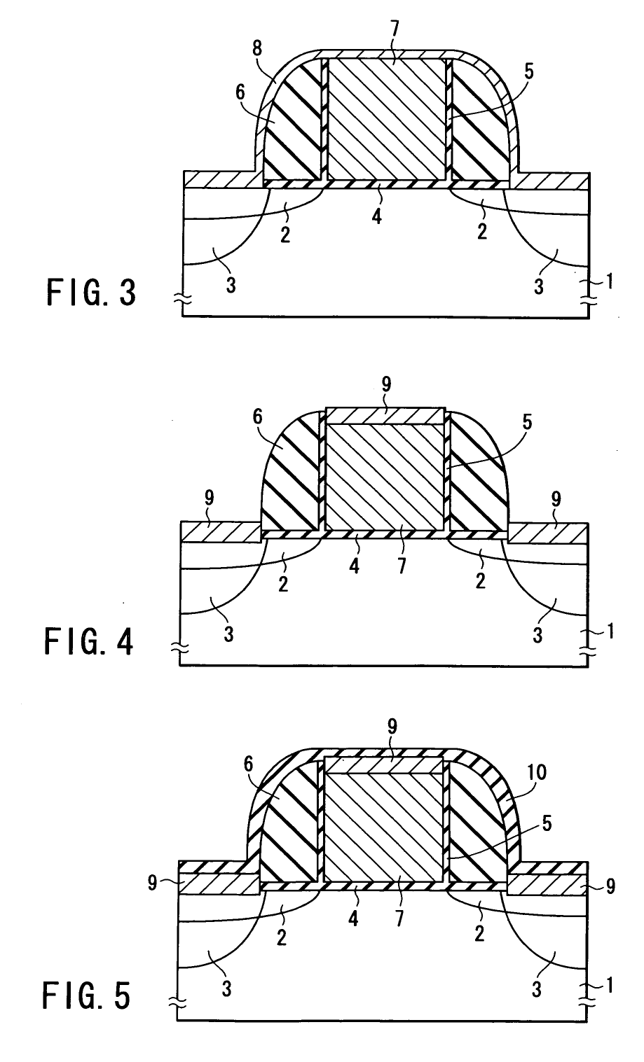

As shown in FIG. 3, the surface of the semiconductor substrate 1 is pretreated with a dilute hydrofluoric acid or the like, and thereafter, a nickel film 8 is deposited over the semiconductor substrate 1 by sputtering so as to cover the exposed surface. A thickness of the nickel film 8 is in the range of 1 to 30 nm.

Thereafter, a heat treatment is carried out, for example, at a temperature of 250° C. to 500° C. for 1 sec to 10 min in an atmosphere of nitrogen or a rare gas by rapid thermal annealing (RTA). At this time, only the nickel film 8 on silicon is transformed to a nickel silicide film 9, and the nickel film 8 on a material other than silicon remains as unreacted. The unreacted nickel film 8 is, as shown in FIG. 4, removed in a mixed chemicals composed of a hydrogen peroxide solution and sulfuric acid.

The silicon nitride film 10 containing carbon is deposited on the semiconductor substrate 1 to a thickness of 1 nm to 150 nm by a reaction between a silicon source and a nitriding species. For example, hexamethyldisilane (Si₂(CH₃)₆:HMD) is used as silicon source and ammonia is used as a nitriding species. A film formation temperature is in the range of 250° C. to 550° C. and a film formation pressure is in the range of 0.01 Torr to 50 Torr. Under such film formation conditions adopted, the nickel silicide film 9 on the silicon electrode 7 containing arsenic or phosphorus is not etched, which makes it possible to form a silicon nitride film (SiN) containing carbon.

Subsequently, the interlayer insulating film 11 such as a silicon oxide film is deposited to a thickness of 100 to 10000 nm, followed by an ordinary processing such as RIE to form a contact hole. The contact hole is filled with the contact 12 such as W through a barrier layer (Ti/TiN).

The wiring layer 14 of a metal such as aluminum or copper is formed on the surface of the interlayer insulating film 11. The contact 12 connects electrically the wiring layer 14 to the nickel silicide 9 on the source-drain regions.

In FIG. 6, there are shown results of an impurity analysis of the silicon nitride film (SiN) formed under film forming conditions described above. In FIG. 6, the ordinate represents a concentration and the abscissa shows a depth (nm) from the surface of the semiconductor substrate. As shown in the figure, it is found that carbon is introduced into the silicon nitride film at a concentration of 1×10²¹ cm⁻³ by using HMD as the silicon source. Furthermore, a chlorine (Cl) concentration in the film is of the order of 1×10¹⁵ cm⁻³.

The presence of carbon in the film enables improvement on a performance and suppression of fluctuations in processing of the semiconductor device. For example, by adding carbon into the silicon nitride film, the film density can decrease to reduce the dielectric constant. With the reduced dielectric constant, suppression is enabled of reduction in speed of the transistor called the RC delay. With addition of carbon into the silicon nitride film, an etching resistance against a chemical liquid is improved, and with improvement on the etching resistance, reduction is in turn enabled in fluctuations in removal of the silicon nitride film during a pretreatment in formation of the contact hole.

The silicon nitride film containing carbon is formed by a reaction between the nitriding species and the silicon source. Since hexamethyldisilane used as the silicon source has a methyl group, carbon and hydrogen are contained into the silicon nitride film formed by the reaction. The film itself becomes of a low density to reduce a dielectric constant and to in turn suppress the reduction in speed of transistor, which is called the RC delay. That is, the high performance of the transistor will be realized. Furthermore, as the silicon source, there can be simultaneously used hexachlorodisilane which has been traditionally used in a technique for forming a low temperature silicon nitride film. In this case, chlorine is contained in the silicon nitride film to be formed. Usage of the silicon nitride film containing carbon will not degrade the conductive layer of the metal silicide for use in the semiconductor device.

While the silicon source used in forming the silicon nitride film is HMD as one example in the above description, there can be used many kinds of silicon sources in which used instead of a methyl group in HMD are other carbon containing groups, an amino group and furthermore, amino groups having carbon compound as a substituent. As examples thereof, there can be given by: an ethyl group (C₂H₆), a propyl group (C₃H₇), a butyl group (C₄H₉), a t-butyl group (C(CH₃)₃) and the like.

As other silicon sources, there can be given by: SiCl₂(R)₂, SiCl(R)₃, disilanes (SiClₓ(R)₆₋ₓ) (x=6 is excluded), and SiClₓR₃₋ₓNHSiCl_{y}R_{3-y} (Cl can be replaced with other halogen elements) wherein R is an alkyl group.

While the nickel silicide is used as the electrode material, other metals than nickel can be given by: Ta, Co, Ti, Mo, Hf, W, Pt and Pd, and similar advantages are obtained in the case where the other metals are used as a material of an electrode not only singly but also in a stacked structure composed of metals thereof.

The insulating film containing carbon described above may contain chlorine at a concentration of 4×10²¹ cm⁻³ or less. HCD may be used as the silicon source together with HMD and hydrogen may be contained at a concentration of 1×10²⁰ cm⁻³ or more.

The insulating film mainly composed of the silicon nitride film described above may also be formed by a reaction of silane having a methyl group or an amino group with ammonia. The insulating film mainly composed of the silicon nitride film described above may also be formed by a reaction of hexamethyldisilane with ammonia. Such insulating film may also be formed by a reaction of hexamethyldisilane and hexachlorodisilane with ammonia. A film forming temperature at which the reaction described above is conducted may be 700° C. or less. The insulating film containing carbon can also contain a halogen element other than chlorine.

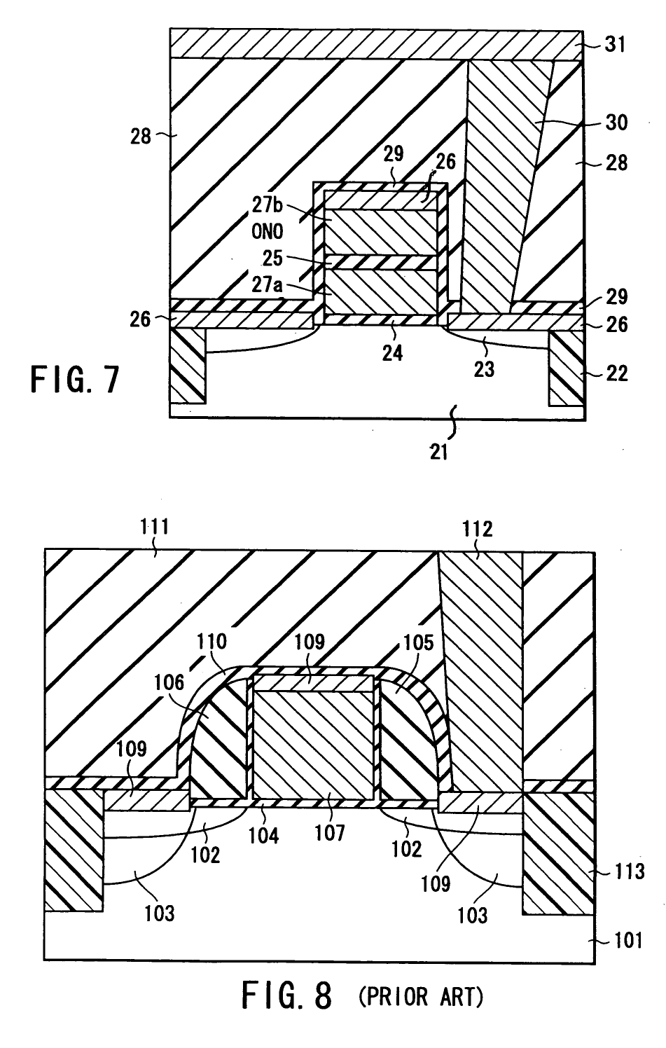

A second embodiment will be described with reference to FIG. 7.

FIG. 7 is a sectional view of a flash memory cell applied thereto. In this semiconductor device as well, the conductive layer of the metal silicide is formed on surfaces of the gate electrode and source/drain regions for the purpose of decreasing the resistance, and the silicon nitride film containing carbon is formed on the surface of the semiconductor substrate.

For example, an isolation region 22 such as STI is formed in a P-type semiconductor substrate 21 and a MOSFET is formed in a defined element region. N-type source/drain regions 23, for example, are formed in a surface region of the semiconductor substrate 21. A gate insulating film 24 such as a silicon oxide film is formed on a channel region between the source/drain regions 23. A gate structure is formed on the gate insulating film 24. That is, a floating gate 27a made of polysilicon is formed on the gate insulating film 24 and a control gate 27b is formed on the floating gate 27a through an insulating film (ONO(Oxide-Nitride-Oxide)) 25.

A conductive layer 26 of a metal silicide such as nickel silicide is formed on the top surface of the control gate 27b. The conductive layer 26 decreases the resistance of the control gate 27b. Simultaneously, the conductive layer 26 is also formed on the source/drain regions 23 in order to decrease the resistance thereof. A silicon nitride film 29 containing carbon is formed on the semiconductor substrate 21 to cover the conductive layer on the gate structure and the source/drain regions. An interlayer insulating film 28 such as a silicon oxide film deposited by CVD or the like is formed over the semiconductor substrate 21 to cover the silicon nitride film 29. In the interlayer insulating film 28, there is formed a contact hole which is to be filled with a contact 30 used for electrically connecting a wiring layer 31, which is formed on the interlayer insulating film 28 after a surface thereof is planarized, and made of aluminum, copper or the like connected to a bit line, with the conductive layer 26 on a drain region of the source/drain regions 23. The contact hole is provided to expose the surface of the conductive layer 26 on the source/drain regions, and the contact 30 such as tungsten or the like filled in the contact hole connects the wiring layer 31 and the conductive layer 26 electrically to each other. The contact hole is formed by anisotropic etching such as RIE and the silicon nitride film 29 containing carbon serves as an etching stopper in the process.

The silicon nitride film 29 containing carbon is deposited on the semiconductor substrate 21 to a thickness of 1 nm to 150 nm by a reaction of a silicon source with a nitriding species. Hexamethyl disilane (Si₂(CH₃)₆:HMD), for example, is used as the silicon source and ammonia is used as a nitriding species. A film forming temperature is in the range of 250° C. to 550° C. and a film forming pressure is in the range of 0.01 Torr to 50 Torr. Under such film forming conditions, a conductive layer made of a metal silicide on a control gate doped with arsenic or phosphorus is not etched, thereby enabling formation of the silicon nitride film containing carbon.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate;
source/drain regions provided in the semiconductor substrate;
a gate insulating film provided on a channel region between the source/drain regions;
a gate electrode provided on the gate insulating film;
a conductive layer of a metal silicide provided on the gate electrode and the source/drain regions;
an insulating film containing carbon provided on the semiconductor substrate so as to be in contact with at least the conductive layer; and
an interlayer insulating film provided on the semiconductor substrate so as to cover the insulating film containing carbon.

2. The semiconductor device according to claim 1, wherein the insulating film containing carbon is mainly composed of a silicon nitride film.

3. The semiconductor device according to claim 2, wherein a content of the carbon is 1×10²⁰ cm⁻³ or more.

4. The semiconductor device according to claim 1, wherein a metal of the metal silicide is nickel.

5. The semiconductor device according to claim 1, wherein a metal of the meal silicide is at least one selected from a group consisting of tantalum, cobalt, titanium, molybdenum, hafnium, tungsten, platinum and palladium.

6. The semiconductor device according to claim 5, wherein a metal of the metal silicide has a stacked structure composed of a plurality of layers.

7. The semiconductor device according to claim 1, wherein the insulating film containing carbon contains chlorine at a concentration of 4×10²¹ cm⁻³ or less.

8. The semiconductor device according to claim 1, wherein the insulating film containing carbon contains hydrogen at a concentration of 1×10²⁰ cm⁻³ or more.

9. A method of manufacturing a semiconductor device, comprising:
forming source/drain regions in a silicon semiconductor substrate;
forming a gate insulating film on a channel region between the source/drain regions;
forming a gate electrode of polysilicon on the gate insulating film;
forming a conductive layer of a metal on the semiconductor substrate so as to cover the gate electrode and the source/drain regions;
heat-treating the conductive layer to form a conductive metal silicide, obtained by a reaction of the silicon and the polysilicon with the metal, on the source/drain regions and the gate electrode;
removing the metal unreacted with the silicon and the polysilicon;
forming an insulating film containing carbon on the semiconductor substrate so as to cover the conductive layer of a metal silicide; and
forming an interlayer insulating film over the semiconductor substrate so as to cover the insulating film containing carbon.

10. The method of manufacturing the semiconductor device according to claim 9, wherein the insulating film containing carbon is mainly composed of a silicon nitride film.

11. The method of manufacturing the semiconductor device according to claim 9, wherein a content of the carbon is 1×10²⁰ cm⁻³ or more.

12. The method of manufacturing the semiconductor device according to claim 9, wherein the metal is nickel.

13. The method of manufacturing the semiconductor device according to claim 9, wherein the metal is at least one selected from a group consisting of tantalum, cobalt, titanium, molybdenum, hafnium, tungsten, platinum and palladium.

14. The method of manufacturing the semiconductor device according to claim 13, wherein the metal has a stacked structure composed of a plurality of layers.

15. The method of manufacturing the semiconductor device according to claim 9, wherein the insulating film containing carbon contains chlorine at a concentration of 4×10²¹ cm⁻³ or less.

16. The method of manufacturing the semiconductor device according to claim 9, wherein the insulating film containing carbon contains hydrogen at a concentration of 1×10²⁰ cm⁻³ or more.

17. The method of manufacturing the semiconductor device according to claim 10, wherein the insulating film mainly composed of the silicon nitride film is formed by a reaction of silane having a methyl group or an amino group with ammonia.

18. The method of manufacturing the semiconductor device according to claim 17, wherein the insulating film mainly composed of the silicon nitride film is formed by a reaction of hexamethyldisilane with ammonia.

19. The method of manufacturing the semiconductor device according to claim 10, wherein the insulating film mainly composed of the silicon nitride film is formed by a reaction of hexamethyldisilane and hexachlorodisilane with ammonia.

20. The method of manufacturing the semiconductor device according to claim 10, wherein a film forming temperature in the reaction is 700° C. or less.
